(19) United States
(12) Patent Application Publication
(10) Pub. No.: US 2023/0290557 A1
(43) Pub. Date: Sep. 14, 2023

(54) COMMON MODE CHOKE COIL AND NOISE FILTER CIRCUIT EQUIPPED WITH SAID COMMON MODE CHOKE COIL

(71) Applicant: Mitsubishi Electric Corporation, Tokyo (JP)

(72) Inventors: Kodai KATAGIRI, Chiyoda-ku, Tokyo (JP); Yuko KUBOTA, Chiyoda-ku, Tokyo (JP); Koichi ARISAWA, Chiyoda-ku, Tokyo (JP); Taizo YAMAOKA, Chiyoda-ku, Tokyo (JP)

(73) Assignee: Mitsubishi Electric Corporation, Tokyo (JP)

(21) Appl. No.: 18/013,552

(22) PCT Filed: Nov. 24, 2020
(86) PCT No.: PCT/JP2020/043645

§ 371 Date: May 15, 2023

(30) Foreign Application Priority Data
Jul. 15, 2020 (JP) 2020-121076

(51) Int. Cl. H01F 17/04; H01F 27/29; H01F 27/28

(52) U.S. Cl. CPC H01F 17/045; H01F 27/29; H01F 27/2828; H01F 2017/0093

(57) ABSTRACT

This common mode choke coil (CC1) comprises: a choke coil including a magnetic core (1) and a covered conductive wire (2a, 2b) wound around the magnetic core (1); a conductor (5) extending along the surface of the magnetic core (1); and a ground conductive wire (6) for grounding the conductor (5). The conductor (5) is disposed at a position in contact with a winding start portion (3a, 3b) of the covered conductive wire (2a, 2b) with respect to the magnetic core (1) and not in contact with or close to a winding end portion (4a, 4b).

### TECHNICAL FIELD

The present disclosure relates to a common mode choke coil used as a noise filter that suppresses electromagnetic noise, and a noise filter circuit equipped with the common mode choke coil.

### BACKGROUND ART

A common mode choke coil and a capacitor to ground may be used as a noise filter for suppressing electromagnetic noise. In order to reduce the number of antinoise components, a common mode choke coil having a function of a capacitor to ground has been proposed.

For example, Japanese Patent Laying-Open No. 2008-118101 (PTL 1) discloses a technique of forming a ground capacitance that functions similarly to a capacitor to ground by disposing a grounded conductor in a magnetic core of a common mode choke coil.

### CITATION LIST

### Patent Literature

PTL 1: Japanese Patent Laying-Open No. 2008-118101

### SUMMARY OF INVENTION

### Technical Problem

In the configuration disclosed in Japanese Patent Laying-Open No. 2008-118101, a grounded conductor is added to the magnetic core to form a ground capacitance, by which electromagnetic noise is bypassed. However, depending on the region in which the conductor is disposed, a path through which electromagnetic noise propagates to the common mode choke coil again via the ground capacitance may be generated, and this may arise a problem that the electromagnetic noise suppression effect is reduced as compared with a conventional common mode choke coil without the conductor. Japanese Patent Laying-Open No. 2008-118101 does not mention such a problem and a countermeasure therefor at all.

The present disclosure has been made to solve the above-described problem, and an object thereof is to improve an electromagnetic noise suppression effect of a common mode choke coil having a function of a capacitor to ground.

### Solution to Problem

The common mode choke coil according to the present disclosure includes: at least one choke coil including a magnetic core and a covered conductive wire wound around the magnetic core; a conductor extending along the surface of the magnetic core; and a ground conductive wire for grounding the conductor. The conductor is disposed at a position in contact with or close to one of a winding start portion and a winding end portion of the covered conductive wire with respect to the magnetic core and not in contact with or close to an other of the winding start portion and the winding end portion.

### Advantageous Effects of Invention

In the common mode choke coil according to the present disclosure, the position of the conductor for forming a ground capacitance is limited to a region that is in contact with or close to one of the winding start portion and the winding end portion of the covered conductive wire and that is not in contact with or close to the other of the winding start portion and the winding end portion. As a result, even if the ground capacitance is formed, a path through which electromagnetic noise propagates to the common mode choke coil again is not generated, so that the electromagnetic noise suppression effect of the common mode choke coil having a function of a capacitor to ground can be improved.

### BRIEF DESCRIPTION OF DRAWINGS

FIG. 1 is a front view (part 1) of a common mode choke coil.

FIG. 2 is a side view (part 1) of the common mode choke coil.

FIG. 3 is a front view (part 2) of a common mode choke coil.

FIG. 4 is a front view (part 3) of a common mode choke coil.

FIG. 5 is a front view (part 4) of a common mode choke coil.

FIG. 6 is a front view (part 5) of a common mode choke coil.

FIG. 7 is a side view (part 2) of the common mode choke coil.

FIG. 8 is a front view (part 6) of a common mode choke coil.

FIG. 9 is a front view (part 7) of a common mode choke coil.

FIG. 10 is a circuit diagram (part 1) of the common mode choke coil.

FIG. 11 is a front view of a common mode choke coil according to a comparative example.

FIG. 12 is a side view of the common mode choke coil according to the comparative example.

FIG. 13 is a circuit diagram of the common mode choke coil according to the comparative example.

FIG. 14 is a diagram illustrating an example of an analysis result of an electromagnetic noise reduction effect.

FIG. 15 is a diagram illustrating another example of the analysis result of the electromagnetic noise reduction effect.

FIG. 16 is a front view (part 8) of a common mode choke coil.

FIG. 17 is a side view (part 3) of the common mode choke coil.

FIG. 18 is a circuit diagram (part 2) of the common mode choke coil.

FIG. 19 is a front view (part 9) of a common mode choke coil.

FIG. 20 is a circuit diagram (part 3) of the common mode choke coil.

FIG. 21 is a front view (part 10) of a common mode choke coil.

FIG. 22 is a front view (part 1) of a noise filter circuit.

FIG. 23 is a front view (part 2) of a noise filter circuit.

### DESCRIPTION OF EMBODIMENTS

Embodiments of the present disclosure will now be described in detail with reference to the drawings. In the following, a plurality of embodiments will be described, but it is planned from the beginning of the filing of the present application to appropriately combine the configurations described in the respective embodiments. In the drawings, the same or corresponding portions are denoted by the same reference numerals, and the description thereof will not be repeated.

### First Embodiment

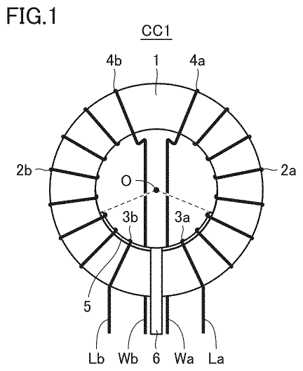

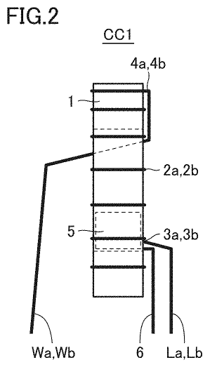

FIG. 1 is a front view of a common mode choke coil CC1 according to the first embodiment. FIG. 2 is a side view of common mode choke coil CC1 according to the first embodiment.

Common mode choke coil CC1 includes a toroidal magnetic core 1 having an annular shape, covered conductive wires 2a and 2b, a conductor 5, and a ground conductive wire 6. Magnetic core 1 and covered conductive wires 2a and 2b constitute a choke coil.

Covered conductive wire 2a is wound around a half (right half in FIG. 1) of magnetic core 1. Covered conductive wire 2a includes a portion wound around magnetic core 1 from a winding start portion 3a to a winding end portion 4a and lead wires La and Wa not wound around magnetic core 1.

Lead wire La is connected to winding start portion 3a, is drawn out from winding start portion 3a to one of lateral surfaces (lateral surface on the front side in FIG. 1) side of magnetic core 1, and extends in the outer diameter direction (downward in FIG. 1) of magnetic core 1. Lead wire Wa is connected to winding end portion 4a, is drawn out from winding end portion 4a to the other lateral surface (lateral surface on the back side in FIG. 1) side of magnetic core 1, and extends in a direction (downward in FIG. 1) same as the direction of lead wire La.

Covered conductive wire 2b is wound around the other half (left half in FIG. 1) of magnetic core 1. Covered conductive wire 2b includes a portion wound around magnetic core 1 from a winding start portion 3b to a winding end portion 4b and lead wires Lb and Wb not wound around magnetic core 1.

Lead wire Lb is connected to winding start portion 3b, is drawn out from winding start portion 3b to one of lateral surfaces (lateral surface on the front side in FIG. 1) side of magnetic core 1, and extends in the outer diameter direction (downward in FIG. 1) of magnetic core 1. Lead wire Wb is connected to winding end portion 4b, is drawn out from winding end portion 4b to the other lateral surface (lateral surface on the back side in FIG. 1) side of magnetic core 1, and extends in a direction (downward in FIG. 1) same as the direction of lead wire Lb.

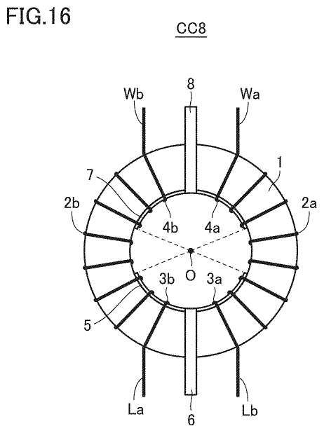

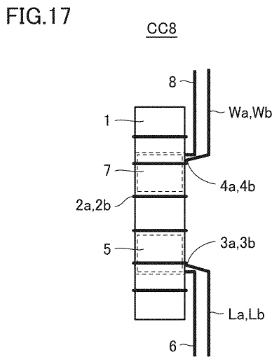

The arrangement of lead wires Wa and Wb is not necessarily limited to the arrangement illustrated in FIG. 1. For example, lead wires Wa and Wb may be drawn out to the same side as lead wires La and Lb (the lateral surface side on the front side in FIG. 1) when viewed from magnetic core 1, and may extend in a direction different from lead wires La and Lb (upward in FIG. 1) (see FIGS. 16 and 17 described later).

Ground conductive wire 6 has a first end connected to conductor 5 and a second end that is grounded. Ground conductive wire 6 is disposed on the same side as lead wires La and Lb when viewed from magnetic core 1. Ground conductive wire 6 is disposed between lead wire La of covered conductive wire 2a and lead wire Lb of covered conductive wire 2b when common mode choke coil CC1 is viewed from front. Ground conductive wire 6 may be made of the same material as conductor 5, or may be constituted by a wiring, a bus bar, or a pattern.

Conductor 5 extends along the inner peripheral surface of magnetic core 1 and is disposed between the inner peripheral surface of magnetic core 1 and covered conductive wires 2a and 2b. The region where conductor 5 is disposed is limited to a partial region of the inner peripheral surface of magnetic core 1. Specifically, conductor 5 is disposed at a position in contact with winding start portions 3a and 3b of covered conductive wires 2a and 2b and not in contact with or close to winding end portions 4a and 4b of covered conductive wires 2a and 2b. Note that conductor 5 is not necessarily limited to being in contact with winding start portions 3a and 3b, and may be close to winding start portions 3a and 3b.

In addition, in the first embodiment, the region where conductor 5 is disposed may be limited to a region having an inferior angle (an angle larger than 0° and smaller than 180°) as viewed from a center O of annular magnetic core 1. Furthermore, in the first embodiment, the region where conductor 5 is disposed may be limited to a region up to portions where covered conductive wires 2a and 2b are wound three times from winding start portions 3a and 3b, respectively. Due to the region where conductor 5 is disposed being limited as described above, the distance between conductor 5 and winding end portions 4a and 4b is larger than the distance between conductor 5 and winding start portions 3a and 3b. In addition, the distance between winding start portions 3a and 3b and winding end portions 4a and 4b of covered conductive wires 2a and 2b is larger than the distance between conductor 5 and winding start portions 3a and 3b of covered conductive wires 2a and 2b.

Further, as shown in FIG. 2, lead wires Wa and Wb may be disposed at positions away from conductor 5 such that the distance between conductor 5 and lead wires Wa and Wb connected to winding end portions 4a and 4b that are not in contact with or close to conductor 5 is larger than the distance between conductor 5 and lead wires La and Lb connected to winding start portions 3a and 3b that are in contact with conductor 5.

Note that conductor 5 only needs to be disposed at a position in contact with or close to one of winding start portions 3a and 3b and winding end portions 4a and 4b of covered conductive wires 2a and 2b and is not in contact with or close to the other. Thus, for example, conductor 5 may be arranged at a position in contact with or close to winding end portions 4a and 4b and not in contact with or close to winding start portions 3a and 3a.

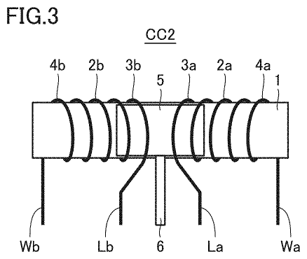

Magnetic core 1 illustrated in FIGS. 1 and 2 has an annular shape, but the shape of magnetic core 1 is not limited thereto. For example, magnetic core 1 may have another closed loop shape such as an elliptical shape, a rectangular shape, or a ladder shape. In addition, magnetic core 1 may have an open loop shape such as an I-shape, a U-shape, or an E-shape. FIG. 3 is a front view of a common mode choke coil CC2 using I-shaped (cylindrical) magnetic core 1.

Although magnetic core 1 illustrated in FIGS. 1 and 2 does not have a gap, magnetic core 1 may have a gap. Although magnetic core 1 illustrated in FIGS. 1 and 2 is not covered with an insulator, the surface of magnetic core 1 may be covered with an insulator. Although magnetic core 1 illustrated in FIGS. 1 and 2 is a bulk body, magnetic core 1 may have a ribbon or nanocrystal structure.

Although covered conductive wires 2a and 2b illustrated in FIGS. 1 and 2 are not in contact with each other, covered conductive wires 2a and 2b may be in contact with each other, or covered conductive wires 2a and 2b may overlap each other and be wound around magnetic core 1.

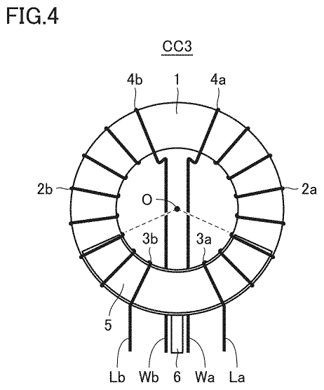

In addition, although conductor 5 illustrated in FIGS. 1 and 2 is disposed along the inner peripheral surface of magnetic core 1, conductor 5 may be disposed along the surface of the magnetic core including the outer peripheral surface or the lateral surface of magnetic core 1 or a region obtained by combining the outer peripheral surface and the lateral surface. FIG. 4 is a front view of a common mode choke coil CC3 in which conductor 5 is disposed along the lateral surface of magnetic core 1.

Although conductor 5 illustrated in FIGS. 1 and 2 is disposed between magnetic core 1 and covered conductive wires 2a and 2b, conductor 5 may be disposed on covered conductive wires 2a and 2b wound around magnetic core 1.

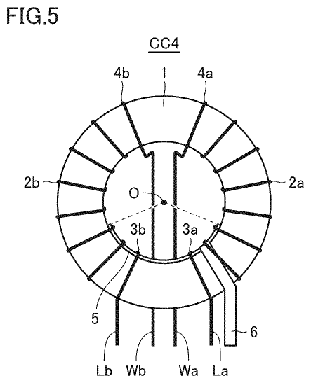

Although ground conductive wire 6 illustrated in FIG. 1 is disposed between lead wires La and Lb, the position of ground conductive wire 6 is not limited thereto. FIG. 5 is a front view of a common mode choke coil CC4 in which ground conductive wire 6 is disposed outside a region between lead wires La and Lb.

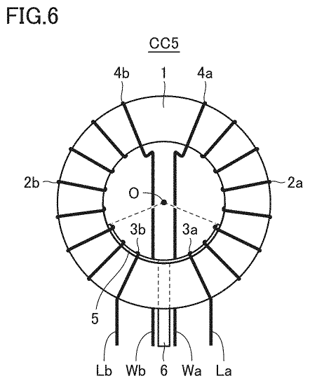

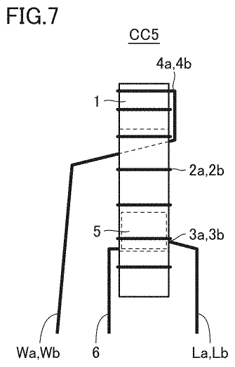

Although ground conductive wire 6 illustrated in FIGS. 1 and 2 is disposed on the same side as lead wires La and Lb when viewed from magnetic core 1, ground conductive wire 6 may be disposed on a side (that is, the same side as lead wires Wa and Wb) different from lead wires La and Lb when viewed from magnetic core 1. FIG. 6 is a front view of a common mode choke coil CC5 in which ground conductive wire 6 is disposed on the same side as lead wires Wa and Wb. FIG. 7 is a side view of common mode choke coil CC5 illustrated in FIG. 6. It is to be noted that, in common mode choke coil CC5, lead wires Wa and Wb are disposed at positions away from ground conductive wire 6 such that the distance between ground conductive wire 6 and lead wires Wa and Wb connected to winding end portions 4a and 4b that are not in contact with or close to conductor 5 is larger than the distance between conductor 5 and lead wires La and Lb connected to winding start portions 3a and 3b that are in contact with conductor 5, as illustrated in FIG. 7.

Although one conductor 5 is disposed in FIGS. 1 and 2, conductor 5 may be divided into a plurality of portions.

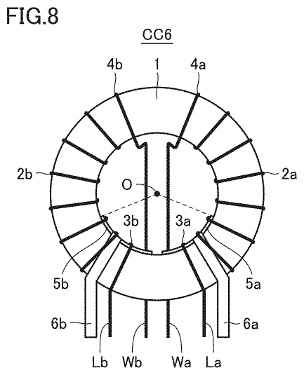

FIG. 8 is a front view of a common mode choke coil CC6 in which a conductor 5a in contact with winding start portion 3a of covered conductive wire 2a and a conductor 5b in contact with winding start portion 3b of covered conductive wire 2b are separately disposed. In common mode choke coil CC6, a ground conductive wire 6a for grounding conductor 5a and a ground conductive wire 6b for grounding conductor 5b are arranged on the same side as lead wires La and Lb when viewed from magnetic core 1.

Note that ground conductive wires 6a and 6b may be disposed on the same side as lead wires Wa and Wb as viewed from magnetic core 1 as long as the distance from lead wires Wa and Wb is sufficiently ensured so that ground conductive wires 6a and 6b are not close to lead wires Wa and Wb.

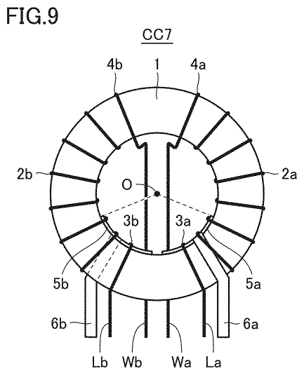

FIG. 9 is a front view of another common mode choke coil CC7 in which conductor 5a in contact with winding start portion 3a of covered conductive wire 2a and conductor 5b in contact with winding start portion 3b of covered conductive wire 2b are separately disposed. In common mode choke coil CC7, ground conductive wire 6a for grounding conductor 5a is arranged on the same side as lead wires La and Lb when viewed from magnetic core 1, and ground conductive wire 6b for grounding conductor 5b is arranged on the different side (same side as lead wires Wa and Wb) from lead wires La and Lb when viewed from magnetic core 1. It is to be noted that, in common mode choke coil CC7, a sufficient distance between ground conductive wire 6b and lead wires Wa and Wb is ensured so that ground conductive wire 6b is not close to lead wires Wa and Wb.

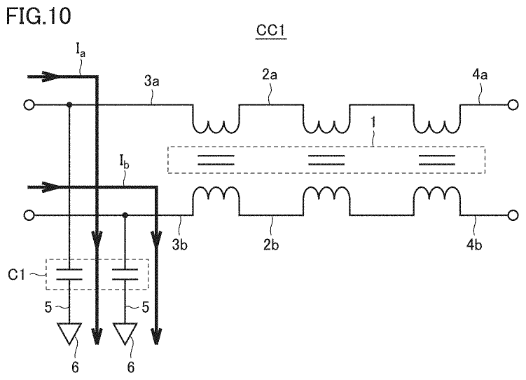

FIG. 10 is a circuit diagram of common mode choke coil CC1 according to the first embodiment. In FIG. 10, ground capacitance C1 is formed by covered conductive wires 2a and 2b, conductor 5 in contact with winding start portions 3a and 3b of covered conductive wires 2a and 2b, and ground conductive wire 6 for grounding conductor 5. Due to the formation of ground capacitance C1, electromagnetic noise paths Ia and Ib passing through ground capacitance C1 are formed.

In common mode choke coil CC1 according to the first embodiment, conductor 5 is in contact with winding start portions 3a and 3b of covered conductive wires 2a and 2b but is away from winding end portions 4a and 4b, and thus, the region where ground capacitance C1 is formed is limited to the periphery of winding start portions 3a and 3b, and the ground capacitance is not formed around winding end portions 4a and 4b.

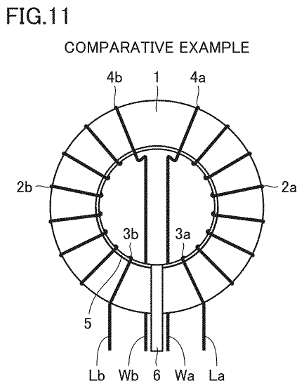

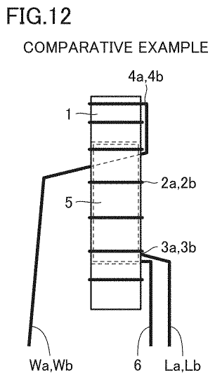

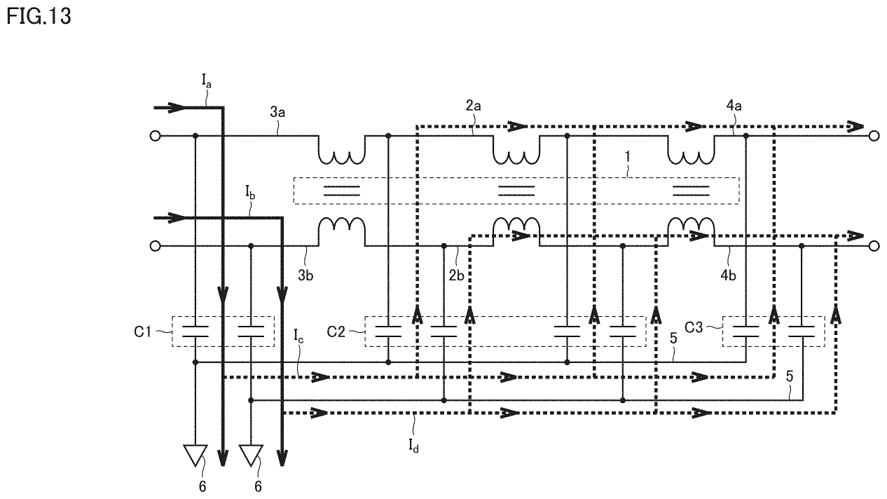

FIG. 11 is a front view of a common mode choke coil according to a comparative example. FIG. 12 is a side view of the common mode choke coil according to the comparative example illustrated in FIG. 11. FIG. 13 is a circuit diagram of the common mode choke coil according to the comparative example illustrated in FIG. 11.

In the comparative example illustrated in FIGS. 11 to 13, a region where conductor 5 is disposed is not limited, and conductor 5 is disposed over the entire inner peripheral surface of magnetic core 1. Therefore, conductor 5 extends over the region from winding start portions 3a and 3b to winding end portions 4a and 4b of covered conductive wires 2a and 2b. As a result, in the common mode choke coil according to the comparative example, ground capacitances C2 and C3 having common grounds to that of ground capacitance C1 are formed not only around winding start portions 3a and 3b but also in the intermediate portions between winding start portions 3a and 3b and winding end portions 4a and 4b and around winding end portions 4a and 4b, respectively. Therefore, in addition to electromagnetic noise paths Ia and Ib passing through ground capacitance C1, electromagnetic noise paths Ic and Id passing through ground capacitances C2 and C3 are formed, so that a path through which electromagnetic noise propagates to the common mode choke coil again occurs.

On the other hand, in common mode choke coil CC1 according to the first embodiment, ground capacitances C2 and C3 are not formed by limiting the region where conductor 5 is disposed as described above, and thus, electromagnetic noise paths Ic and Id passing through ground capacitances C2 and C3 are not formed. With this configuration, a more significant electromagnetic noise suppression effect than that of the comparative example can be obtained.

In addition, in common mode choke coil CC1 according to the first embodiment, the distance between winding start portions 3a and 3b and winding end portions 4a and 4b of covered conductive wires 2a and 2b is larger than the distance between conductor 5 and covered conductive wires 2a and 2b. Thus, the formation of an inter-terminal capacitance of common mode choke coil CC1 is suppressed. That is, if the inter-terminal capacitance of the common mode choke coil, that is, the capacitance having winding start portions 3a and 3b and winding end portions 4a and 4b of covered conductive wires 2a and 2b as both ends is formed, an electromagnetic-noise bypass path passing through the inter-terminal capacitance is formed, by which the electromagnetic noise suppression effect may be reduced. In view of this, in common mode choke coil CC1 according to the first embodiment, the distance between winding start portions 3a and 3b and winding end portions 4a and 4b of covered conductive wires 2a and 2b is larger than the distance between conductor 5 and covered conductive wires 2a and 2b, by which the formation of the inter-terminal capacitance of common mode choke coil CC1 is prevented.

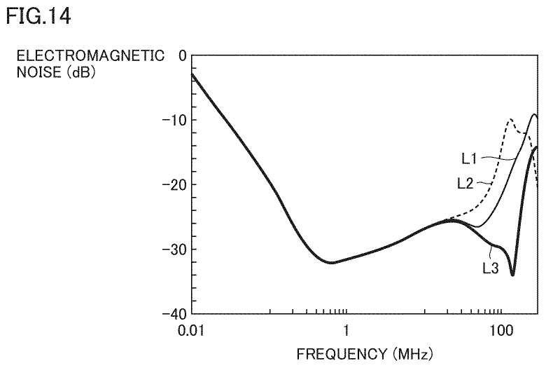

FIG. 14 is a diagram illustrating an example of an analysis result of the electromagnetic noise reduction effect. In FIG. 14, the horizontal axis represents frequency (unit: MHz) in logarithm, and the vertical axis represents electromagnetic noise (unit: dB). In FIG. 14, a curved line L1 indicates an analysis result of a common mode choke coil not including conductor 5. A curved line L2 indicates an analysis result of the common mode choke coil (see FIGS. 11 to 13) of the comparative example in which conductor 5 is disposed over the entire inner peripheral surface of magnetic core 1. A curved line L3 indicates an analysis result of common mode choke coil CC1 according to the first embodiment. It can be understood from FIG. 14 that common mode choke coil CC1 according to the first embodiment significantly improves the electromagnetic noise suppression effect as compared with the common mode choke coil not including conductor 5 and the common mode choke coil according to the comparative example.

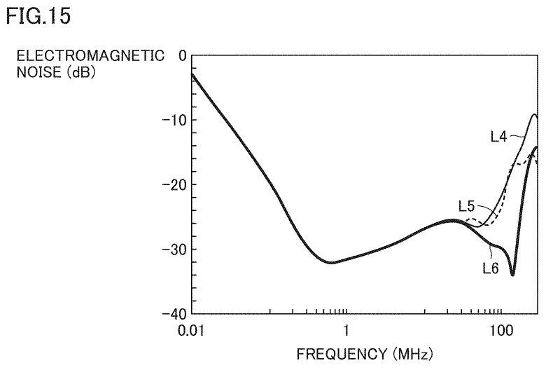

FIG. 15 is a diagram illustrating another example of the analysis result of the electromagnetic noise reduction effect. In FIG. 15, the horizontal axis and the vertical axis are the same as those in FIG. 14 described above. In FIG. 15, a curved line L4 indicates an analysis result of a common mode choke coil not including conductor 5. A curved line L5 indicates an analysis result in a case where the region where conductor 5 is disposed has a straight angle (180°) as viewed from the center of magnetic core 1, or in a case where the region where conductor 5 is disposed is set to a region up to portions where covered conductive wires 2a and 2b are wound four times from winding start portions 3a and 3b, respectively. A curved line L6 indicates an analysis result of common mode choke coil CC1 according to the first embodiment. As an example of common mode choke coil CC1, FIG. 15 shows an analysis result in a case where the region where conductor 5 is disposed is limited to a region up to a right angle (90°) as viewed from the center of magnetic core 1, or in a case where the region where conductor 5 is disposed is limited to a region up to portions where covered conductive wires 2a and 2b are wound three times from winding start portions 3a and 3b, respectively.

Curved line L5 indicates that only a slight electromagnetic noise suppression effect is obtained with respect to the effect indicated by curved line L4 not including conductor 5. This is because an electromagnetic-noise bypass path passing through ground capacitances C1 and C2 is formed due to the generation of ground capacitance C2 having conductor 5 and the intermediate portion of covered conductive wires 2a and 2b as both ends.

On the other hand, in common mode choke coil CC1 according to the first embodiment, the region where conductor 5 is disposed is limited to a region up to portions where covered conductive wires 2a and 2b are wound three times from winding start portions 3a and 3b, respectively. Thus, the generation of ground capacitance C2 is prevented. Therefore, as indicated by curved line L6, it can be understood that the electromagnetic noise reduction effect is improved as compared with curved lines L4 and L5. Note that, as described above, a similar effect can be obtained by limiting the region where conductor 5 is disposed to a region up to a right angle (90°) as viewed from the center of magnetic core 1.

As described above, in common mode choke coil CC1 according to the first embodiment, the position of conductor 5 for forming the ground capacitance with covered conductive wires 2a and 2b is limited to a region in contact with winding start portions 3a and 3b of covered conductive wires 2a and 2b and not in contact with or close to winding end portions 4a and 4b. With this configuration, the region in which the ground capacitance is formed is limited to the periphery of winding start portions 3a and 3b of covered conductive wires 2a and 2b, and the formation of the ground capacitance around winding end portions 4a and 4b of covered conductive wires 2a and 2b can be suppressed. Therefore, it is possible to suppress formation of a path through which noise returns from conductor 5 to winding end portions 4a and 4b of covered conductive wires 2a and 2b. As a result, the electromagnetic noise suppression effect of common mode choke coil CC1 having a function of a capacitor to ground can be improved.

Further, in common mode choke coil CC1 according to the first embodiment, the distance between conductor 5 and lead wires (second lead wire) Wa and Wb connected to winding end portions 4a and 4b that are not in contact with or close to conductor 5 is larger than the distance between conductor 5 and lead wires (first lead wire) La and Lb connected to winding start portions 3a and 3b that are in contact with conductor 5 (see FIG. 2). With this configuration, a sufficient distance can be ensured between conductor 5 and lead wires Wa and Wb connected to winding end portions 4a and 4b, so that it is possible to more appropriately prevent the formation of the ground capacitance around winding end portions 4a and 4b of covered conductive wires 2a and 2b.

In addition, in common mode choke coil CC1 according to the first embodiment, the region where conductor 5 is disposed is limited to a region having an inferior angle (an angle larger than 0° and smaller than 180°) as viewed from center O of magnetic core 1 having an annular shape. This configuration can more appropriately limit the region where the ground capacitance is formed as compared with the case where the region where conductor 5 is disposed has a straight angle) (180° or a reflex angle (an angle larger than 180°) as viewed from center O of magnetic core 1.

Furthermore, in common mode choke coil CC1 according to the first embodiment, the region where conductor 5 is disposed is limited to a region up to portions where covered conductive wires 2a and 2b are wound three times from winding start portions 3a and 3b, respectively. With this configuration, the region where the ground capacitance is formed can be more appropriately limited as compared with the case where conductor 5 is disposed in a region up to portions where covered conductive wires 2a and 2b are wound four or more times from winding start portions 3a and 3b, respectively.

In addition, in common mode choke coil CC1 according to the first embodiment, the distance between winding start portions 3a and 3b and winding end portions 4a and 4b of covered conductive wires 2a and 2b is larger than the distance between conductor 5 and covered conductive wires 2a and 2b (that is, the distance between conductor 5 and winding start portions 3a and 3b of covered conductive wires 2a and 2b). With this configuration, it is possible to suppress formation of a stray capacitance between winding start portions 3a and 3b and winding end portions 4a and 4b of covered conductive wires 2a and 2b. Therefore, it is possible to suppress the electromagnetic noise from being bypassed at both ends of common mode choke coil CC1 via the stray capacitance.

### Second Embodiment

FIG. 16 is a front view of a common mode choke coil CC8 according to the second embodiment. FIG. 17 is a side view of common mode choke coil CC8 according to the second embodiment.

Common mode choke coil CC8 is obtained by adding a conductor 7 and a ground conductive wire 8 to common mode choke coil CC1 illustrated in FIG. 1 described above and changing the arrangement of lead wires Wa and Wb. The other configurations of common mode choke coil CC8 are the same as those of common mode choke coil CC1 described above, and thus, the detailed description thereof will not be repeated here.

Conductor 7 is provided separately from conductor 5. Conductor 7 is disposed at a position facing conductor 5 on the inner peripheral surface of magnetic core 1. Specifically, conductor 7 is disposed at a position not in contact with and close to winding start portions 3a and 3b of covered conductive wires 2a and 2b and in contact with winding end portions 4a and 4b of covered conductive wires 2a and 2b. The region where conductor 7 is disposed may be limited to a region having an inferior angle (an angle larger than 0° and smaller than 180°) as viewed from a center O of annular magnetic core 1. Furthermore, the region where conductor 7 is disposed may be limited to a region up to portions where covered conductive wires 2a and 2b are wound three times from winding end portions 4a and 4b, respectively. Note that, although conductors 5 and 7 illustrated in FIGS. 16 and 17 are disposed along the inner peripheral surface of magnetic core 1, conductors 5 and 7 may be disposed along the surface of the magnetic core including the outer peripheral surface or the lateral surface of magnetic core 1 or a region obtained by combining the outer peripheral surface and the lateral surface.

Ground conductive wire 8 is provided separately from ground conductive wire 6. Ground conductive wire 8 has a first end connected to conductor 7 and a second end that is grounded. Ground conductive wire 8 is disposed on the same side as ground conductive wire 6 when viewed from magnetic core 1.

The other configurations of conductor 7 and ground conductive wire 8 are basically the same as those of conductor 5 and ground conductive wire 6, respectively, and can be modified in the same manner as conductor 5 and ground conductive wire 6 as long as no technical contradiction occurs.

Furthermore, in the second embodiment, lead wires Wa and Wb are arranged on the same side as lead wires La and Lb when viewed from magnetic core 1, and extend from winding end portions 4a and 4b in a direction away from conductor 5 (upward in FIGS. 16 and 17).

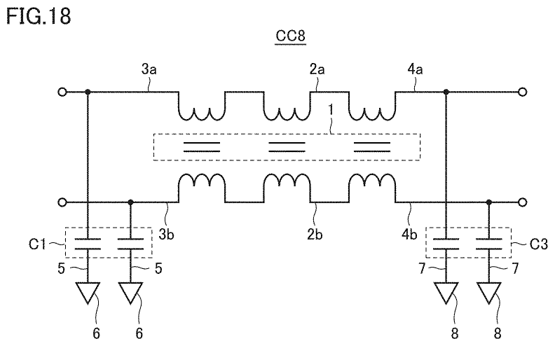

FIG. 18 is a circuit diagram of common mode choke coil CC8 according to the second embodiment. As illustrated in FIG. 18, ground capacitance C1 is formed by covered conductive wires 2a and 2b, conductor 5 in contact with winding start portions 3a and 3b of covered conductive wires 2a and 2b, and ground conductive wire 6 for grounding conductor 5. Due to the formation of ground capacitance C1, electromagnetic noise paths Ia and Ib (see FIG. 10) that pass through ground capacitance C1 and that are not present in a conventional common mode choke coil are formed.

In common mode choke coil CC1 according to the first embodiment described above, conductor 5 is in contact with winding start portions 3a and 3b of covered conductive wires 2a and 2b, but is separated from winding end portions 4a and 4b. Therefore, in common mode choke coil CC1, the formation range of ground capacitance C1 is limited to the periphery of winding start portions 3a and 3b, and the ground capacitance is not formed around winding end portions 4a and 4b, as illustrated in FIG. 10.

On the other hand, in common mode choke coil CC8 according to the second embodiment, ground capacitance C3 different from ground capacitance C1 is formed at the other end of common mode choke coil CC8 by winding end portions 4a and 4b of covered conductive wires 2a and 2b, conductor 7, and ground conductive wire 8 in addition to ground capacitance C1, as shown in FIG. 18.

In the comparative example shown in FIG. 13 described above, ground capacitances C1 and C3 formed at both ends of the common mode choke coil are both grounded by ground conductive wire 6 of same conductor 5. Therefore, this configuration may form a path through which electromagnetic noise propagated to conductor 5 via ground capacitance C1 is propagated from conductor 5 to the common mode choke coil again via ground capacitance C3.

On the other hand, in the second embodiment, ground conductive wire 6 of conductor 5 forming ground capacitance C1 and ground conductive wire 8 of conductor 7 forming ground capacitance C3 are provided separately from each other. Therefore, a path through which the electromagnetic noise propagated to conductor 5 via ground capacitance C1 is propagated from conductor 5 to common mode choke coil CC8 again via ground capacitance C3 is not formed. Similarly, a path through which the electromagnetic noise propagated to conductor 7 via ground capacitance C3 is propagated to common mode choke coil CC8 again via ground capacitance C1 is not formed. Therefore, common mode choke coil CC8 according to the second embodiment can provide a more significant electromagnetic noise suppression effect than that of the comparative example shown in FIG. 13.

Furthermore, in the comparative example illustrated in FIG. 13 described above, ground capacitance C2 having a ground common to that of ground capacitance C1 is also formed around the intermediate portion between winding start portions 3a and 3b and winding end portions 4a and 4b of covered conductive wires 2a and 2b. Therefore, this configuration may form a path through which the electromagnetic noise propagated to conductor 5 via ground capacitance C1 or ground capacitance C3 is propagated from conductor 5 to the common mode choke coil again via ground capacitance C2.

On the other hand, in the second embodiment, the region where each of conductors 5 and 7 is disposed is limited to a region having an inferior angle (an angle larger than 0° and smaller than 180°) as viewed from center O of magnetic core 1. Thus, in common mode choke coil CC8 according to the second embodiment, the formation of ground capacitance C2 around the intermediate portion between winding start portions 3a and 3b and winding end portions 4a and 4b of covered conductive wires 2a and 2b can be prevented.

As described above, common mode choke coil CC8 according to the second embodiment includes, separately from conductor 5, another conductor 7 which is not in contact with or close to winding start portions 3a and 3b of covered conductive wires 2a and 2b and which is in contact with winding end portions 4a and 4b. Furthermore, common mode choke coil CC8 according to the second embodiment further includes another ground conductive wire 8 for grounding another conductor 7, separately from ground conductive wire 6 for grounding conductor 5. Thus, ground capacitances C1 and C3 independent of each other can be formed around winding start portions 3a and 3b and around winding end portions 4a and 4b of covered conductive wires 2a and 2b, respectively.

### Third Embodiment

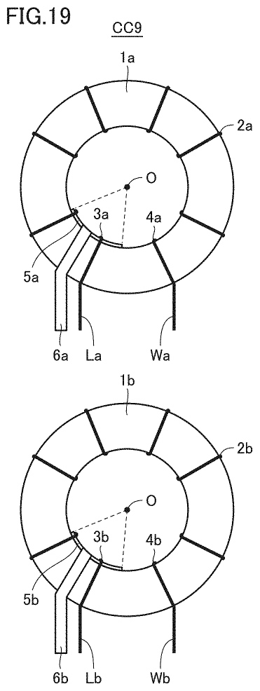

FIG. 19 is a front view of a common mode choke coil CC9 according to the third embodiment. Common mode choke coil CC9 is formed by magnetically coupling a first choke coil including a magnetic core 1a, a covered conductive wire 2a, a conductor 5a, and a ground conductive wire 6a, and a second choke coil including a magnetic core 1b, a covered conductive wire 2b, a conductor 5b, and a ground conductive wire 6b.

Covered conductive wire 2a is wound around magnetic core 1a. Conductor 5a extends along the inner peripheral surface of magnetic core 1a and is disposed between the inner peripheral surface of magnetic core 1a and covered conductive wire 2a. Conductor 5a is disposed at a position in contact with winding start portion 3a of covered conductive wire 2a and not in contact with or close to winding end portion 4a of covered conductive wire 2a. The region where conductor 5a is disposed is limited to a region having an angle of less than 90° as viewed from center O of magnetic core 1a. The distance between winding start portion 3a and winding end portion 4a of covered conductive wire 2a is larger than the distance between conductor 5a and covered conductive wire 2a (that is, the distance between conductor 5a and winding start portion 3a of covered conductive wire 2a). Ground conductive wire 6a has a first end connected to conductor 5a and a second end that is grounded.

Covered conductive wire 2b is wound around magnetic core 1b. Conductor 5b extends along the inner peripheral surface of magnetic core 1b and is disposed between the inner peripheral surface of magnetic core 1b and covered conductive wire 2b. Conductor 5b is disposed at a position in contact with winding start portion 3b of covered conductive wire 2b and not in contact with or close to winding end portion 4b of covered conductive wire 2b. The region where conductor 5b is disposed is limited to a region having an angle of less than 90° as viewed from center O of magnetic core 1b. The distance between winding start portion 3b and winding end portion 4b of covered conductive wire 2b is larger than the distance between conductor 5b and covered conductive wire 2b (that is, the distance between conductor 5b and winding start portion 3b of covered conductive wire 2b). Ground conductive wire 6b has a first end connected to conductor 5b and a second end that is grounded.

The other configurations of magnetic cores 1a and 1b, covered conductive wires 2a and 2b, conductors 5a and 5b, and ground conductive wires 6a and 6b are basically the same as those of magnetic core 1, covered conductive wires 2a and 2b, conductor 5, and ground conductive wire 6 of common mode choke coil CC1 illustrated in FIG. 1 described above, and can be modified in the same manner as magnetic core 1, covered conductive wires 2a and 2b, conductor 5, and ground conductive wire 6 as long as no technical contradiction occurs.

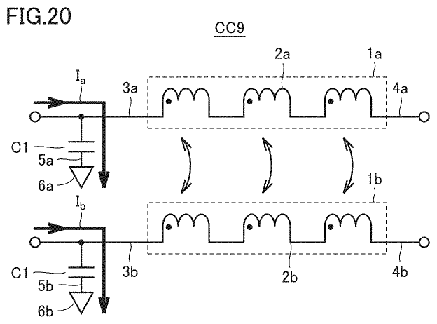

FIG. 20 is a circuit diagram of common mode choke coil CC9 according to the third embodiment. In common mode choke coil CC9, when a magnetic field leaking from magnetic core 1a and a magnetic field leaking from magnetic core 1b are coupled with each other, an effect same as the effect (see FIG. 10) of common mode choke coil CC1 according to the first embodiment described above can be obtained. Therefore, common mode choke coil CC9 according to the third embodiment can provide a more significant electromagnetic noise suppression effect than that of the comparative example (see FIGS. 11 to 13) described above.

### Fourth Embodiment

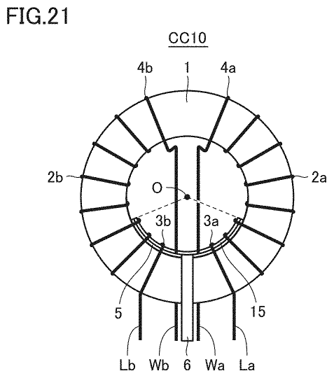

FIG. 21 is a front view of a common mode choke coil CC10 according to the fourth embodiment. Common mode choke coil CC10 is obtained by inserting a dielectric 15 into at least a part between conductor 5 and covered conductive wires 2a and 2b in common mode choke coil CC1 described in the first embodiment.

With this structure, an effect similar to that of the common mode choke coil described in the first embodiment can also be obtained. Furthermore, with this configuration, ground capacitance C1 generated between conductor 5 and covered conductive wires 2a and 2b can be increased, so that the electromagnetic-noise bypass effect by ground capacitance C1 can be further enhanced. Therefore, common mode choke coil CC10 according to the fourth embodiment can provide a more significant electromagnetic noise suppression effect than that of the comparative example (see FIGS. 11 to 13) described above.

### Fifth Embodiment

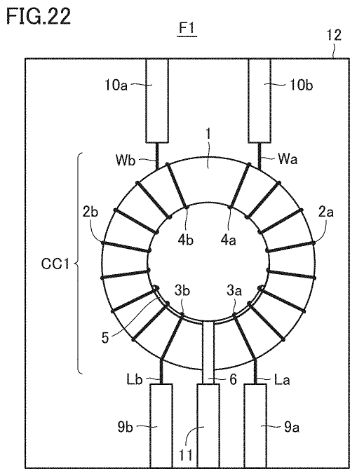

FIG. 22 is a front view of a noise filter circuit F1 according to the fifth embodiment. Noise filter circuit F1 includes common mode choke coil CC1 in the above-described first embodiment and a substrate 12. Substrate 12 includes input terminals 9a and 9b, output terminals 10a and 10b, and a ground terminal 11.

Lead wires La and Lb of common mode choke coil CC1 are connected to input terminals 9a and 9b of substrate 12, respectively, and lead wires Wa and Wb are connected to output terminals 10a and 10b of substrate 12, respectively.

Ground conductive wire 6 of common mode choke coil CC1 is connected to ground terminal 11 of substrate 12. Although ground terminal 11 illustrated in FIG. 22 is disposed in parallel with input terminals 9a and 9b, it may not be in parallel with input terminals 9a and 9b. In addition, ground terminal 11 may be provided in a housing having a reference potential.

In noise filter circuit F1 according to the fourth embodiment, a ground capacitance is added to common mode choke coil CC1, whereby an excellent electromagnetic noise suppression effect can be obtained with the number of capacitors to ground which are components of the noise filter being reduced.

Although the above-described noise filter circuit F1 does not have a capacitor to ground, a capacitor to ground may be added between input terminals 9a and 9b and ground terminal 11. Similarly, a capacitor to ground may be added between output terminals 10a and 10b and ground terminal 11.

Further, the common mode choke coil included in noise filter circuit F1 may be changed to any one of other common mode choke coils CC2 to CC8 instead of common mode choke coil CC1. In this case, the positions of input terminals 9a and 9b, output terminals 10a and 10b, and ground terminal 11 of substrate 12 may be changed in accordance with the positions of the covered conductive wires and the ground conductive wire of the changed common mode choke coil.

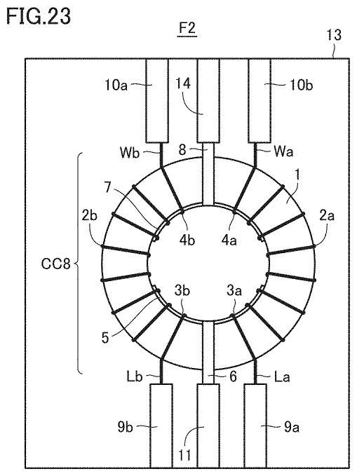

FIG. 23 is a front view of another noise filter circuit F2 according to the fourth embodiment. Noise filter circuit F2 includes common mode choke coil CC8 in the above-described second embodiment and a substrate 13. Substrate 13 is obtained by adding a ground terminal 14 connected to ground conductive wire 8 of common mode choke coil CC8 to substrate 12 illustrated in FIG. 22 described above. In noise filter circuit F2 described above, the ground capacitance is added to common mode choke coil CC1, whereby an excellent electromagnetic noise suppression effect can be obtained with the number of capacitors to ground which are components of the noise filter being reduced.

Note that input terminals 9a and 9b and ground terminal 11 may be disposed close to each other so as to face each other and/or output terminals 10a and 10b and ground terminal 14 may be disposed close to each other so as to face each other.

The impedance between covered conductive wires 2a and 2b and ground terminals 11 and 14 is divided into a frequency region in which the capacitive components of ground capacitances C1 and C2 are dominant and a frequency region in which the inductive components (parasitic inductances) of ground conductive wires 6 and 8 and ground terminal 11 are dominant Therefore, as the parasitic inductances of ground conductive wires 6 and 8 and ground terminal 11 are smaller, the impedance between covered conductive wires 2a and 2b and ground terminals 11 and 14 can be made smaller, and the electromagnetic-noise bypass effect by ground capacitances C1 and C2 can be further enhanced in the frequency region where the inductive components are dominant.

With this configuration, the direction of current of the electromagnetic noise propagated to input terminals 9a and 9b and output terminals 10a and 10b and the direction of current of the electromagnetic noise propagated to ground terminals 11 and 14 are opposite to each other. Therefore, the parasitic inductance generated in ground terminals 11 and 14 can be reduced, and the electromagnetic-noise bypass effect by ground capacitance C1 can be further enhanced. Similarly, lead wires La and Lb and ground conductive wire 6 may be disposed close to each other so as to face each other and/or lead wires Wa and Wb and ground conductive wire 8 may be disposed close to each other so as to face each other. With this configuration, the parasitic inductance of ground conductive wires 6 and 8 can be reduced, and the electromagnetic-noise bypass effect by ground capacitance C1 can be further enhanced.

In the present embodiment, input terminals 9a and 9b, ground terminal 11, output terminals 10a and 10b, and ground terminal 14 are disposed close to each other so as to face each other on the same plane of substrate 13, but the present invention is not limited thereto. Substrate 13 may be formed as a multilayer substrate, and the above components may be disposed close to each other so as to face each other in the direction perpendicular to the plane of the substrate.

It should be understood that the embodiments disclosed herein are illustrative in all respects and not restrictive. The scope of the present disclosure is defined not by the above description but by the claims, and is intended to include meanings equivalent to the claims and all modifications within the scope.

### REFERENCE SIGNS LIST

1, 1a, 1b: magnetic core, 2a, 2b: covered conductive wire, 3a, 3b: winding start portion, 4a, 4b: winding end portion, 5, 5a, 5b, 7: conductor, 6, 6a, 6b, 8: ground conductive wire, 9a, 9b: input terminal, 10a, 10b: output terminal, 11, 14: ground terminal, 12, 13: substrate, 15: dielectric, C1, C2, C3: ground capacitance, CC1 to CC10: common mode choke coil, F1, F2: noise filter circuit, La, Lb, Wa, Wb: lead wire

1. A common mode choke coil comprising:
at least one choke coil including a magnetic core and a covered conductive wire wound around the magnetic core;
a conductor extending along a surface of the magnetic core; and
a ground conductive wire for grounding the conductor,
wherein
the conductor is disposed at a position in contact with or close to one of a winding start portion and a winding end portion of the covered conductive wire with respect to the magnetic core and not in contact with or close to an other of the winding start portion and the winding end portion.

2. The common mode choke coil according to claim 1, wherein
the covered conductive wire includes a first lead wire connected to the one of the winding start portion and the winding end portion and a second lead wire connected to the other of the winding start portion and the winding end portion, and
a distance between the second lead wire and the conductor is larger than a distance between the first lead wire and the conductor.

3. The common mode choke coil according to claim 1 or 2, wherein the at least one choke coil includes a plurality of the choke coils magnetically coupled.

4. The common mode choke coil according to any one of claims 1 to 3, wherein
the magnetic core has an annular shape, and
a region where the conductor is disposed is limited to a region having an inferior angle when viewed from a center of the magnetic core.

5. The common mode choke coil according to any one of claims 1 to 4, wherein a region where the conductor is disposed is limited to a region up to a portion where the covered conductive wire is wound three times from the winding start portion.

6. The common mode choke coil according to any one of claims 1 to 5, wherein a distance between the winding start portion and the winding end portion is larger than a distance between the conductor and the covered conductive wire.

7. The common mode choke coil according to any one of claims 1 to 6, further comprising a dielectric disposed in at least a portion between the conductor and the covered conductive wire.

8. The common mode choke coil according to any one of claims 1 to 7, further comprising:
another conductor provided separately from the conductor and not in contact with or close to the one of the winding start portion and the winding end portion but in contact with or close to the other of the winding start portion and the winding end portion; and
another ground conductive wire provided separately from the ground conductive wire and for grounding the other conductor.

9. A noise filter circuit comprising:
the common mode choke coil according to any one of claims 1 to 8; and
a substrate including an input terminal, an output terminal, and a ground terminal,
wherein
the input terminal and the output terminal are respectively connected to a first end and a second end of the covered conductive wire, and
the ground terminal is connected to the ground conductive wire.

10. The noise filter circuit according to claim 9, wherein at least one of the input terminal and the output terminal is disposed close to the ground terminal so as to face the ground terminal.

11. The noise filter circuit according to claim 9 or 10, wherein
the covered conductive wire includes two lead wires respectively connected to the winding start portion and the winding end portion, and
at least one of the two lead wires is disposed close to the ground conductive wire so as to face the ground conductive wire.
